(19) United States
(12) Patent Application Publication
(10) Pub. No.: US 2012/0194980 A1
(43) Pub. Date: Aug. 2, 2012

(54) ELECTRONIC APPARATUS

(75) Inventors: Hiroyuki Oda, Nagano (JP); Junichi Tadano, Nagano (JP); Kenji Saito, Nagano (JP); Ryosuke Tobiyama, Tokyo (JP)

(73) Assignee: SONY CORPORATION, Tokyo (JP)

(21) Appl. No.: 13/356,794

(22) Filed: Jan. 24, 2012

(30) Foreign Application Priority Data
Jan. 31, 2011 (JP) P2011-018011

(51) Int. Cl. H05K 7/00

(52) U.S. Cl. 361/679.01

(57) ABSTRACT

An electronic apparatus includes a first outer member configured to form a first exterior surface, a second outer member configured to form a second exterior surface that is opposite to the first exterior surface, and a battery unit configured to form part of the second exterior surface when the battery unit is contained in the second outer member. The battery unit has a battery cell integrated thereinto. The battery cell supplies electric power. The first outer member, the second outer member, and the battery unit are fastened together by using a screw member.

### CROSS-REFERENCE TO RELATED APPLICATION

The present application claims priority from Japanese Patent Application No. JP 2011-018011 filed in the Japanese Patent Office on Jan. 31, 2011, the entire content of which is incorporated herein by reference.

### BACKGROUND

The present technology relates to an electronic apparatus and, in particular, to an electronic apparatus having an increased rigidity.

In recent years, mobile electronic apparatuses that users can carry, such as notebook personal computers, have been in widespread use. In order to increase the portability of such electronic apparatuses, it is desirable that the thicknesses of the electronic apparatuses be reduced.

For example, in order to reduce the thickness of a notebook personal computer, a new idea of the layout of the internal components in the body and the structure of a keyboard have been proposed (refer to, for example, Japanese Unexamined Patent Application Publication No. 2010-140510).

### SUMMARY

It is desirable that the thickness of an electronic apparatus be reduced without reducing the rigidity of the electronic apparatus with respect to an external force. The structure described in Japanese Unexamined Patent Application Publication No. 2010-140510 can increase the rigidity of the keyboard portion with respect to an impact caused by a key touch operation by incorporating the input keys of the keyboard into a low-profile box case. However, Japanese Unexamined Patent Application Publication No. 2010-140510 does not describe how the overall rigidity of the apparatus is increased.

Accordingly, the present technology provides an electronic apparatus having an increased rigidity.

According to an embodiment of the present technology, an electronic apparatus includes a first outer member configured to form a first exterior surface, a second outer member configured to form a second exterior surface that is opposite to the first exterior surface, and a battery unit configured to form part of the second exterior surface when the battery unit is contained in the second outer member. The battery unit has a battery cell integrated thereinto. The battery cell supplies electric power. The first outer member, the second outer member, and the battery unit are fastened together by using a screw member.

The battery unit can be contained in the second outer member so that a long side of the second outer member is parallel to a long side of the battery unit.

The screw member can be inserted through the second interior surface of the battery unit and fasten the first outer member, the second outer member, and the battery unit together.

A head portion of the screw member can be formed from an elastic member, and the screw member can fasten the first outer member, the second outer member, and the battery unit together so that at least part of the head portion protrudes from the second exterior surface.

A surface of the head portion that is parallel to the second exterior surface can have a slot formed therein, and the slot can pass through a rotation axis of the screw member.

According to the embodiment of the present technology, the first outer member that forms the first exterior surface, the second outer member that forms the second exterior surface that is opposite to the first exterior surface, and a battery unit having a battery cell that supplies electric power integrated thereinto and that forms part of the second exterior surface when the battery unit is contained in the second outer member are fastened together by using the screw member.

According to the embodiment of the present technology, the rigidity can be increased.

### BRIEF DESCRIPTION OF THE DRAWINGS

FIG. 1 is a perspective view of a notebook personal computer according to an embodiment of the present technology;

FIG. 2 is a front view of the notebook personal computer with a cover of the body closed;

FIG. 3 is a bottom view of the body of the notebook personal computer;

FIG. 4 is a front cross-sectional view of the body of the notebook personal computer;

FIG. 5 is a perspective view of a screw used in the notebook personal computer; and

FIG. 6 is a cross-sectional view of the screw used in the notebook personal computer.

### DETAILED DESCRIPTION OF EMBODIMENTS

Exemplary embodiments of the present technology are described below with reference to the accompanying drawings.

### Structure of Notebook Personal Computers

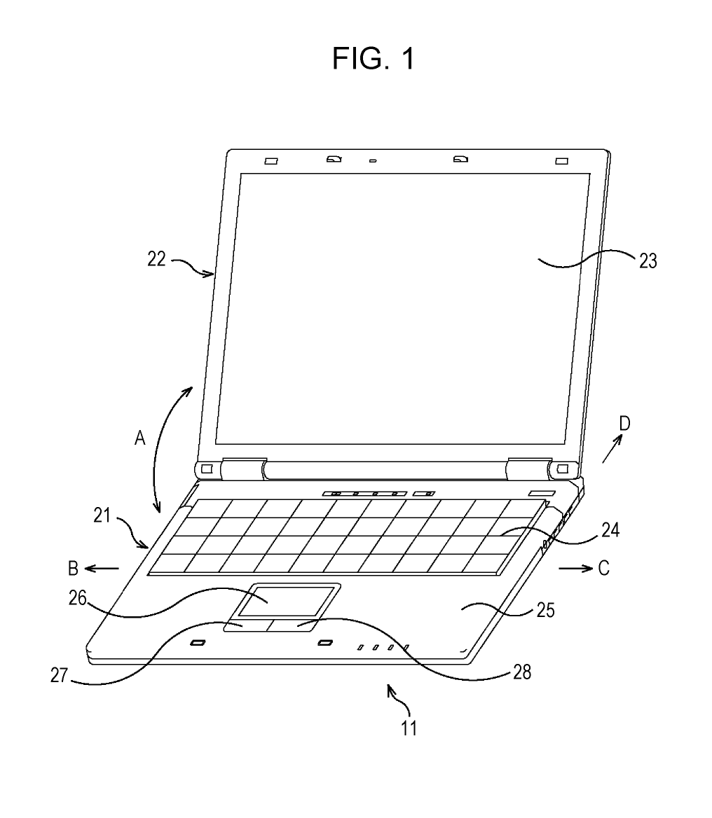

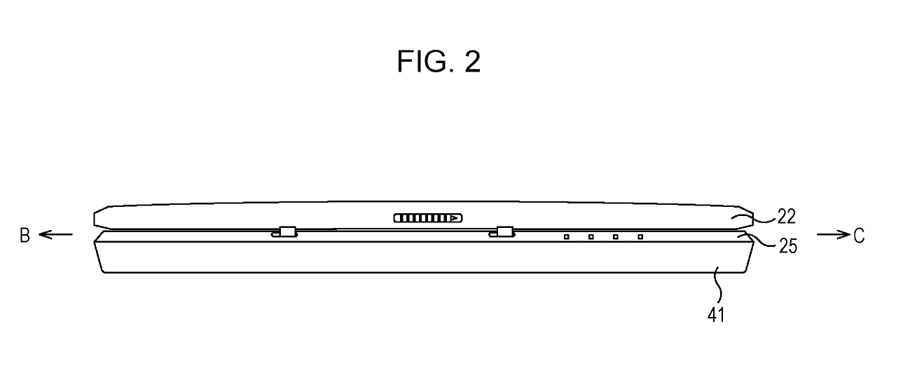

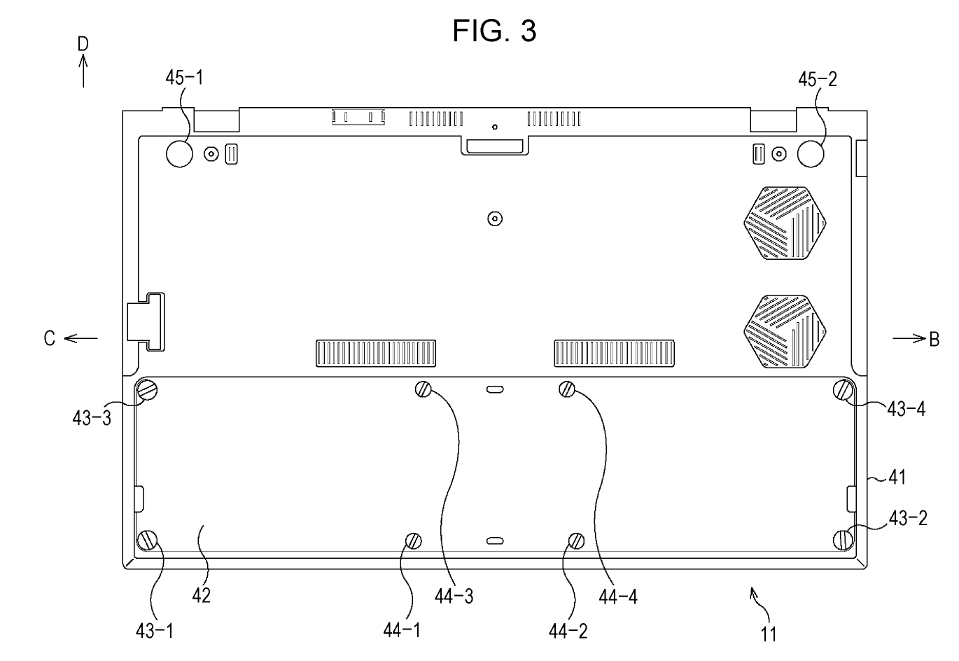

FIGS. 1 to 3 illustrate the structure of a notebook personal computer representing an electronic apparatus according to an exemplary embodiment of the present technology. FIG. 1 is a perspective view of a notebook personal computer 11 (hereinafter simply referred to as a “personal computer 11”). FIG. 2 is a front view of the personal computer 11 with a cover member closed with respect to the body of the personal computer 11. FIG. 3 is a bottom view of a body 21 of the personal computer 11.

The notebook personal computer 11 includes the body 21 and a cover member 22 attached to the body 21 so as to be flippable with respect to the body 21, as indicated by an arrow A illustrated in FIG. 1. The cover member 22 of the personal computer 11 is attached to an end of the body 21 in a direction indicated by an arrow D using hinge portions rotatable about an axis line extending in the right-left direction (a direction indicated by an arrow B (the left direction) and a direction indicated by an arrow C (the right direction)).

Using such a structure, the personal computer 11 can switch between an open mode in which the cover member 22 stands up (refer to FIG. 1) and a closed mode in which the cover member 22 overlaps the body 21 (refer to FIG. 2) by rotating the cover member 22 with respect to the body 21.

Note that the directions indicated by arrows B in FIGS. 1 to 3 correspond to one another. Similarly, the directions indicated by arrows C in FIGS. 1 to 3 correspond to one another, and the directions indicated by arrows D in FIGS. 1 to 3 correspond to one another.

The cover member 22 includes a flat liquid crystal display (LCD) 23 serving as a display for displaying text and images.

A keyboard 24 is disposed on the top surface of the body 21. The keyboard 24 serves as one of operation units for a user to operate the personal computer 11. The keyboard 24 includes a plurality of keys, such as alphabet keys, a numerical keypad, and a variety of function keys. The keyboard 24 is horizontally long. The keyboard 24 is disposed so as to be located in the distal end area of the top surface of the body 21 (the distal end area indicated by the direction of an arrow D). In addition, a palm rest 25 is formed in the proximal end area of the top surface of the body 21 (the proximal end area in a direction opposite to the direction of the arrow D). That is, the palm rest 25 forms part of the top exterior surface of the body 21.

In addition, the palm rest 25 includes a touch pad 26, a left click button 27, and a right click button 28 serving as operation units arranged therein. The touch pad 26 is substantially square in shape. In the palm rest 25, the touch pad 26 is located substantially in the middle of the body 21 in the right-left direction and is located so as to be close to the keyboard 24. In the palm rest 25, the left click button 27 and the right click button 28 are located substantially in the middle of the body 21 in the right-left direction and are located so as to be on the proximal side of the touch pad 26 and be adjacent to each other in the right-left direction of the body 21. Note that the touch pad 26 is one of pointing devices.

A bottom 41 serves as the bottom portion of the body 21. That is, as illustrated in FIG. 2, the bottom 41 forms an exterior surface (a bottom surface) that is opposite to the exterior surface formed by the palm rest 25 (the top surface). The bottom 41 has a substantially flat box shape. The bottom 41 has internal parts, such as a board including electronic components, arranged therein.

In addition, as illustrated in FIG. 3, the bottom 41 located on the bottom of the body 21 includes a buttery unit 42. The buttery unit 42 includes a buttery cell that supplies electric power to the personal computer 11.

The bottom 41 has a concave portion having a shape that is the same as the shape of the buttery unit 42 at a location corresponding to the palm rest 25 located on the top surface of the body 21. The concave portion can contain the buttery unit 42. The overhead shape of the buttery unit 42 is a rectangle with a long side that is slightly shorter than the width of the body 21 in the right-left direction. Alternatively, the buttery unit 42 has an overhead shape similar to the above-described overhead shape. The buttery unit 42 has a flat 3D shape with a thickness (a height) that is smaller than that of the bottom 41. In this way, the buttery unit 42 is contained in the bottom 41 so that the long side of the buttery unit 42 is parallel to the long side of the bottom 41 (the long side of the body 21).

The buttery unit 42 is configured so that a rechargeable battery cell is integrated into an outer member that forms part of the bottom surface of the body 21. When the buttery unit 42 is contained in the concave portion of the bottom 41, the buttery unit 42 forms the bottom surface of the body 21 together with the bottom 41.

In addition, the buttery unit 42 is secured to the concave portion of the bottom 41 with screws 43-1 to 43-4 serving as screw members screwed at the four corners of the buttery unit 42. In addition, the buttery unit 42 is secured to the concave portion of the bottom 41 with screws 44-1 to 44-4 at four points in substantially the middle of the buttery unit 42 in the right-left direction. That is, the buttery unit 42 is secured to the bottom surface of the body 21 using the screws 43-1 to 43-4 and the screws 44-1 to 44-4.

Note that in the following description, when distinction among the screws 43-1 to 43-4 is not necessary, the screws 43-1 to 43-4 are simply and collectively referred to as the “screws 43”. Similarly, when distinction among the screws 44-1 to 44-4 is not necessary, the screws 44-1 to 44-4 are simply and collectively referred to as the “screws 44”.

### Cross-Sectional View of Notebook Personal Computer

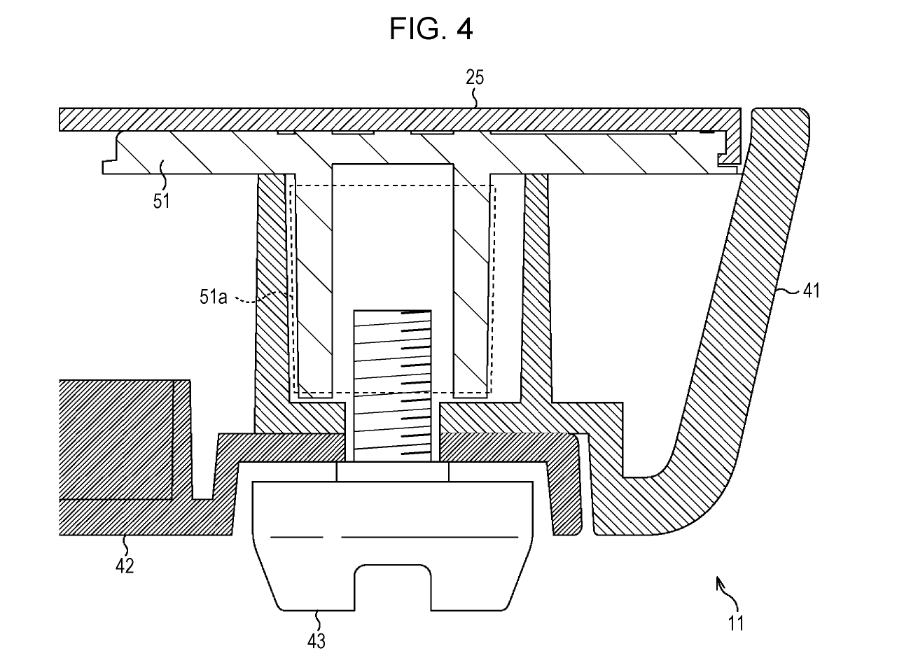

The structure in which the buttery unit 42 is secured to the bottom surface of the body 21 using the screws 43 and 44 is described below with reference to FIG. 4.

FIG. 4 is a front cross-sectional view of the body 21 of the personal computer 11 at the locations of the screws 43 for securing the buttery unit 42 and the vicinity thereof.

As illustrated in FIG. 4, a palm rest supporting unit 51 for supporting the palm rest 25 with respect to the bottom 41 is joined to the inner wall of the palm rest 25. The palm rest supporting unit 51 includes a cylinder portion 51a into which each of the screws 43 is to be screwed. In order to screw the screw 43 into the cylinder portion 51a, an insert nut may be provided inside of the cylinder portion 51a. Alternatively, the screw 43 may be a self tap screw. In addition, each of the bottom 41 and the buttery unit 42 has a through-hole that allows the screw 43 to pass therethrough at the location corresponding to the cylinder portion 51a.

That is, the screw 43 passes through the through-hole of the buttery unit 42 and the bottom 41 from the bottom surface of the body 21 and screws into the cylinder portion 51a of the palm rest supporting unit 51. In this way, the screw 43 fastens the palm rest supporting unit 51, the bottom 41, and the buttery unit 42 together. Note that in FIG. 4, the palm rest supporting unit 51 is separated from the palm rest 25. However, the palm rest supporting unit 51 and the palm rest 25 may be integrated into one part. In such a case, the screw 43 fastens the palm rest 25, the bottom 41, and the buttery unit 42 together.

The above description has been made with reference to the structure in which the buttery unit 42 is secured using the screws 43. Note that the structure regarding the screws 44 has a similar structure.

In general, the buttery unit 42 that is configured by integrating a battery cell having a rigidity that is higher than that of the casing of an electronic apparatus and the outer member into one body has a rigidity higher than that of each of the palm rest 25 and the bottom 41 of the body 21. Accordingly, by employing the above-described structure in which the palm rest 25 (the palm rest supporting unit 51), the bottom 41, and the buttery unit 42 are fastened together with the screws 43, the rigidity of the body 21 of the personal computer 11 can be increased.

For example, an existing low-profile notebook personal computer has a concave portion for containing a battery cell in part of the bottom. In addition, the notebook personal computer has a cover that covers the concave portion. By opening and closing the cover, the battery cell can be removed and attached. In such a structure, a relatively large gap is formed between the inner wall of the concave portion provided in the bottom and the battery cell and between the cover and the battery cell. In terms of the rigidity of such a notebook personal computer with respect to an external force exerted onto an end of the body of the notebook personal computer in the right-left direction (a direction of the long side), the rigidity of the battery cell does not contribute to the rigidity of the notebook personal computer due to the presence of the gap. Thus, the rigidity of the notebook personal computer is substantially the same as the rigidity of the palm rest or the bottom. If a user grasps one end of the body of the notebook personal computer in the right-left direction and lifts the notebook personal computer, the body may deflect. Accordingly, the user may become worried about whether the notebook personal computer has sufficient rigidity when handling the notebook personal computer.

Accordingly, as illustrated in FIG. 3, by placing the buttery unit 42 in the bottom 41 so that the right-left direction of the body 21 (the long side of the body 21) is parallel to the right-left direction of the buttery unit 42 (the long side of the buttery unit 42) and fastening the palm rest 25, the bottom 41, and the buttery unit 42 together using the screws 43 and the screws 44, the rigidity of the body 21 of the personal computer 11 with respect to an external force exerted onto an end of the body 21 in the right-left direction of the personal computer 11 (the long side of the personal computer 11) is made substantially the same as the rigidity of the buttery unit 42. Thus, even when the user grasps one end of the body 21 of the notebook personal computer 11 in the right-left direction and lifts the notebook personal computer 11, deflection occurring in the body 21 can be reduced and, therefore, the user does not become worried about whether the notebook personal computer has sufficient rigidity when handling the personal computer 11.

Referring back to FIG. 3, in order to stably place the personal computer 11 on an installation surface, such as a desk surface, rubber feet 45-1 and 45-2, which are elastic members, are provided at the corners of the bottom 41 on the side on which the concave portion for containing the buttery unit 42 is not provided (on the side indicated by the direction of an arrow D) so as to protrude from the bottom surface of the body 21.

In addition, the head portion of each of the above-described screws 43-1 to 43-4 is formed of an elastic member, such as elastomer (rubber). At least part of the head portion protrudes from the bottom surface of the body 21. In this way, the screws 43-1 to 43-4 secure the buttery unit 42 to the bottom surface of the body 21. That is, the screws 43-1 to 43-4 have a function that is the same as the function of the rubber feet 45-1 and 45-2.

By forming the head portions of the screws 43-1 to 43-4 using an elastic material in the above-described manner, the number of components can be reduced, as compared with a structure in which the screws and the rubber feet are separately arranged. Thus, the design of arrangement of the components on the bottom surface of the body 21 of the personal computer 11 can be simplified. In addition, the number of the manufacturing steps and the cost of the components of the personal computer 11 can be reduced.

In addition, even in the case where the structure is compared with a structure in which the rubber feet are mounted in the through-holes of the buttery unit 42 so as to cover the screws for securing the buttery unit 42, the number of components can be reduced. In such a case, although the designs of arrangement of the components on the bottom surface of the body 21 are the same, the number of the manufacturing steps and the cost of the components of the personal computer 11 can be reduced.

### Structure of Screw

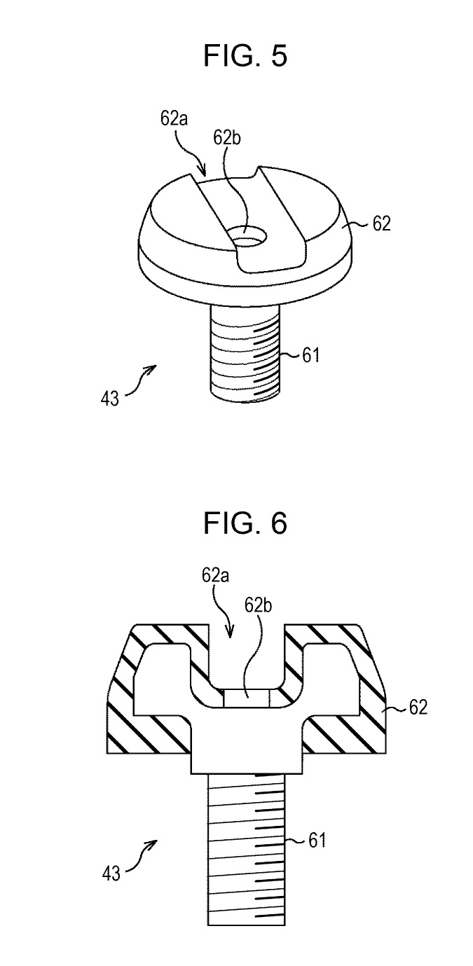

The structure of the screw 43 is described in detail below with reference to FIGS. 5 and 6. FIG. 5 is a perspective view of the screw 43. FIG. 6 is a cross-sectional view of the screw 43 viewed when the screw 43 is cut by a plane including the rotation axis of the screw 43.

The screw 43 includes a shaft portion 61 and a head portion 62.

The shaft portion 61 is formed from a metal member. The shaft portion 61 has a spiral groove on the side surface of a cylinder sub-portion so that the screw 43 functions as a male thread. As noted above, the spiral groove may be provided so that the screw 43 functions as a self tap screw. Note that the shaft portion 61 alone can function as a screw having a shaft portion and a head portion.

As described above, the head portion 62 is formed from an elastic member, such as elastomer (rubber). The head portion 62 is formed by integrating the head of the shaft portion 61 formed from a metal member into the elastic member. In addition, a slot 62a is formed on a surface of the head portion 62 that is parallel to the bottom surface of the body 21 when the screw 43 is inserted and disposed in the body 21 of the personal computer 11 (i.e., a surface brought into contact with a mounting surface of the personal computer 11 when the personal computer 11 is placed on the mounting surface). The slot 62a of the head portion 62 is formed so as to pass through the rotation axis of the screw 43. The width of the slot 62a is substantially the same as the width of a coin. The bottom surface of the slot 62a serving as a groove is formed so as to form a gentle curved line (an arc). The groove extends so as to form a downward convex shape from an end of the groove toward the middle of the groove along the length direction of the groove.

In addition, in the middle of the bottom surface of the slot 62a, that is, at the intersection of the bottom surface of the slot 62a and the rotation axis of the screw 43, a recessed seat 62b is provided.

During manufacturing of the personal computer 11, in order to insert the screw 43 through the bottom surface of the body 21, an electric driver having a head portion that can fit into the slot 62a and the recessed seat 62b of the head portion 62 is used. That is, the shape of the head portion of the electric driver has a thickness substantially the same as the width of a coin and has an arc corresponding to the shape of the groove of the slot 62a. In addition, the topmost section of the electric driver (i.e., the section serving as the rotation center of the shaft of the electric driver) has a protrusion that corresponds to the recessed seat 62b. When the protrusion fits into the recessed seat 62b, the rotation center of the shaft of the electric driver is coaxial with the rotation axis of the screw 43. Thus, the screw 43 can be accurately inserted.

Although not shown, unlike the structure of the screw 43, the head portion of the screw 44 is formed from a metallic material that is the same as the material of the shaft portion. In addition, after the palm rest supporting unit 51, the bottom 41, and the buttery unit 42 are fastened together, the head portion does not protrude from the bottom surface of the body 21. However, like the structure of the screw 43, the head portion has a slot and a recessed seat.

As described above, the width of the slot 62a of the head portion 62 of the screw 43 (and the screw 44) is substantially the same as the width of a coin. Accordingly, if the buttery unit 42 is replaced due to, for example, deterioration of the battery cell, it is not necessary for the user to prepare a dedicated electric driver as described above. The user can easily loosen the screw 43 (and the screw 44) using a coin or its equivalent.

While the exemplary embodiment has been described with reference to application to a notebook personal computer, the embodiment of the technology is applicable to operation terminals having no display, tablet terminals including a display integrated into an operation unit, and other low-profile electronic apparatuses.

It should be understood by those skilled in the art that the embodiment of the present technology is not limited to the above-described embodiment, and various modifications, combinations, sub-combinations and alterations may occur depending on design requirements and other factors insofar as they are within the scope of the appended claims or the equivalents thereof.

What is claimed is:

1. An electronic apparatus comprising:
a first outer member configured to form a first exterior surface;
a second outer member configured to form a second exterior surface that is opposite to the first exterior surface; and
a battery unit configured to form part of the second exterior surface when the battery unit is contained in the second outer member, the battery unit having a battery cell integrated thereinto, the battery cell supplying electric power;
wherein the first outer member, the second outer member, and the battery unit are fastened together by using a screw member.

2. The electronic apparatus according to claim 1, wherein the battery unit is contained in the second outer member so that a long side of the second outer member is parallel to a long side of the battery unit.

3. The electronic apparatus according to claim 1, wherein the screw member is inserted through the second interior surface of the battery unit and fastens the first outer member, the second outer member, and the battery unit together.

4. The electronic apparatus according to claim 3, wherein a head portion of the screw member is formed from an elastic member, and wherein the screw member fastens the first outer member, the second outer member, and the battery unit together so that at least part of the head portion protrudes from the second exterior surface.

5. The electronic apparatus according to claim 4, wherein a surface of the head portion that is parallel to the second exterior surface has a slot formed therein, and the slot passes through a rotation axis of the screw member.
